(19) United States
(12) Patent Application Publication
(10) Pub. No.: US 2009/0197405 A1
(43) Pub. Date: Aug. 6, 2009

(54) METHOD OF FORMING A LAYER OVER A SURFACE OF A FIRST MATERIAL EMBEDDED IN A SECOND MATERIAL IN A STRUCTURE FOR A SEMICONDUCTOR DEVICE

(75) Inventors: Wim Besling, Eindhoven (NL); Sonarith Chhun, La Trinite (FR)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/096,231

(22) PCT Filed: Dec. 4, 2006
(86) PCT No.: PCT/IB2006/054584

§ 371 Date: Aug. 27, 2008

(30) Foreign Application Priority Data
Dec. 7, 2005 (EP) 05301019.5

(51) Int. Cl. H01L 21/768

(52) U.S. Cl. 438/653; 257/E21.584

(57) ABSTRACT

There is described a method of forming a barrier layer (6, 110) over a surface of a copper line (3, 107) embedded in a dielectric material (2, 100) in an interconnect structure for a semiconductor device. The barrier layer (6, 110) is selectively deposited over the surface of the copper line (3, 107) by a vapour deposition step and the surface of the dielectric material (2, 100) is treated prior to the vapour deposition step to inhibit deposition of the barrier layer (6, 110) there on during the vapour deposition step. Preferably, the vapour deposition step comprises atomic layer deposition.

The present invention relates to a method of forming a layer over a surface of a first material embedded in a second material in a structure for a semiconductor device. In particular but exclusively the invention relates to a method of forming a diffusion barrier over a metal line embedded in a di-electric in an interconnect structure.

In standard copper interconnect integration schemes for integrated circuit dies, a dielectric barrier is deposited full sheet on top of the inter level dielectric (ILD) and copper lines after the step of chemical mechanical polishing (CMP). The barrier has two roles, 1) to prevent copper diffusion into a dielectric and 2) to act as a via etch stop liner.

A general problem with known SiN and SiC barriers is the weak interface between the copper lines and the overlying barrier. This weak interface causes early reliability failures because of decreased electromigration resistance. Moreover, electrical field concentration is largest near the top of the copper lines which enhances local copper migration and stress induced voiding.

The ability to deposit materials on selected locations only during the manufacture of an integrated circuit is advantageous because it eliminates the need for expensive patterning steps to define deposition areas. For instance, it is envisaged that so called self-aligned barriers (SAB) will replace dielectric barrier films for metal line capping in advanced Cu dual damascene processing. SAB's (CoWP, etc) are mainly applied to improve electro migration resistance and reduce capacitative coupling between adjacent metal lines.

Current integration schemes for self-aligned barriers make use of a selective, electroless process based on the catalytic activation of the metallic surface that is to be capped. The catalyst, typically palladium, is first predominantly deposited on the metal lines and subsequently, barriers are deposited over the lines in an electroless-plating bath. The palladium catalyses the selective self aligned growth of the barriers over the lines. Any palladium that is deposited between the metal lines must be meticulously removed to avoid excessive current leakage from the lines when in use. As the palladium activation is never 100% selective towards copper, the activation and cleaning step is very critical in integration. In this approach, selectivity is achieved by making the metallic part of the surface catalytically reactive. The disadvantage of this approach is that only metallic films can be deposited on top of metallic surfaces.

Known electroless CoWP deposition processes result in increased line heights that cause any gains in capacitance to be partly lost. In addition, electroless grown films tend to grow in a lateral direction thereby reducing the dielectric spacing. This leads to an increased capacitative coupling between the lines and so reduced reliability. These processes may also cause metallic deposition between metal lines resulting in degraded leakage current properties.

It is also known in the art to use Physical Vapour Deposition (PVD) to deposit metallic TaN/Ta barriers over copper lines. Two different approaches are known to date. Briefly, a first approach involves lithographic patterning of the metallic barriers in order to remove metallic barrier in between the copper lines. A second approach involves recess creation in the copper lines and filling these areas with a barrier. In the first approach an extra mask step is needed which is costly. Moreover, any misalignment error results in complete barrier removal on one side of the line. In the second approach the copper lines are recessed by CMP over polish or by wet chemical etching. The PVD barrier is then deposited over dielectric and metal lines. In a second CMP step the barrier on the field is removed leaving a TaN/Ta barrier cap on the recessed copper lines. The disadvantages of this approach are 1) the Cu recess is difficult to control especially for different line widths, 2) the Cu etch back consumes Cu space increasing the resistivity, 3) two CPM steps are needed which is costly, and 4) the etch back step may diffuse/destroy the low-k properties of the intermetal dielectric.

It is desirable to provide new selective deposition processes to grow selectively metallic or non-metallic films on dielectrics or metals and which alleviate at least some of the above mentioned problems.

According to the present invention there is provided a method of forming a layer over a surface of a first material embedded in a second material in a structure for a semiconductor device, in which method the layer is selectively deposited over the surface of the first material by a vapour deposition step and wherein a surface of the second material is treated prior to the vapour deposition step to inhibit deposition of the layer there on during the vapour deposition step.

In a preferred embodiment the vapour deposition step comprises an atomic layer deposition step.

The treatment step may convert the surface of the second material from a hydrophilic surface into a hydrophobic surface.

In one embodiment the treatment step converts the surface of the second material, which is a dielectric, from a hydrophilic surface into a hydrophobic surface.

Prior to the treatment step the surface of the second material substantially terminates in hydroxyl groups and following the treatment step the surface of the second material substantially terminates in methyl groups.

This may be achieved by exposing the surface of the second material to hexamethyl disilazane (HMDS) vapour.

In an alternative embodiment the surface of the second material is treated with an acidic clean, for example a HF wet clean or a HF vapour clean to render the surface hydrophobic.

In an alternative embodiment, the treatment step comprises, depositing a layer of resist material across the surface of the first material and across the surface of the second material, irradiating the layer of resist material with lithographic flux such that reflection of the flux by the first material causes a region of the resist material substantially above the first material to develop before one or more regions of the resist material substantially above the second material, removing the region of the resist material substantially above the first material without removing the one or more regions of the resist material substantially above the second material.

The invention is particularly useful for depositing diffusion barrier layers above metal lines in interconnect structures for semi conductor devices.

An embodiment of the invention will now be described by way of example only with reference to the accompanying drawings in which:

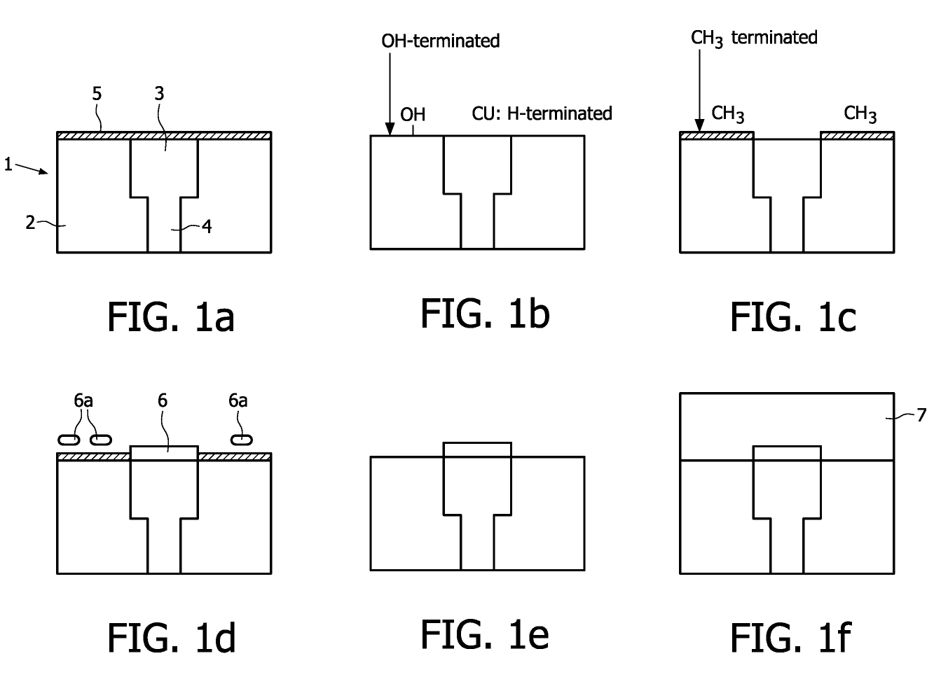

FIGS. 1a to 1f are schematic diagrams illustrating the fabrication of a structure for a semi conductor device;

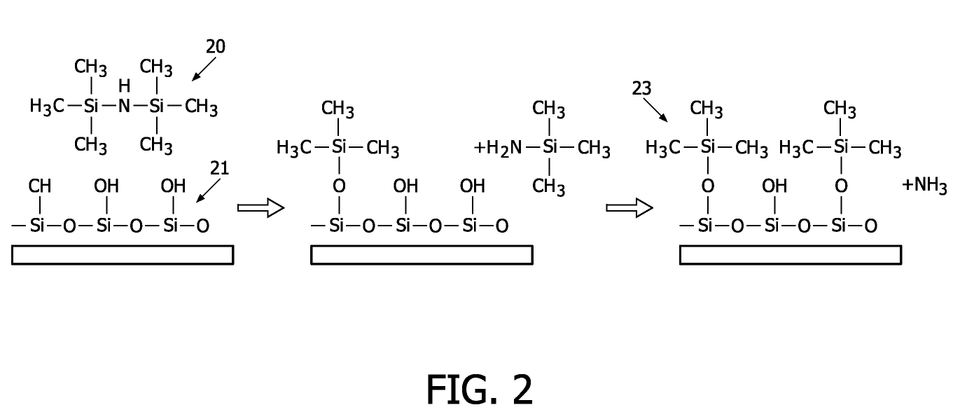

FIG. 2 illustrates HMDS vapour being deposited on a surface;

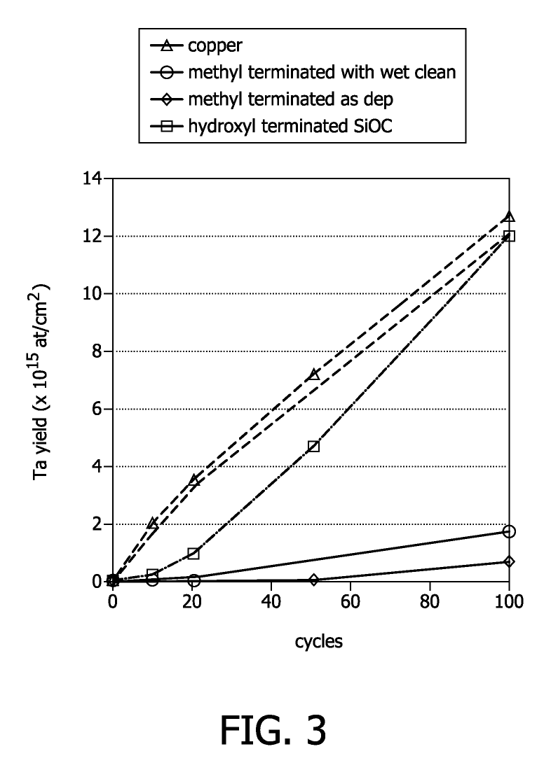

FIG. 3 illustrates a graph of the amount of Ta as a function of number of cycles deposited by ALD on various surface types;

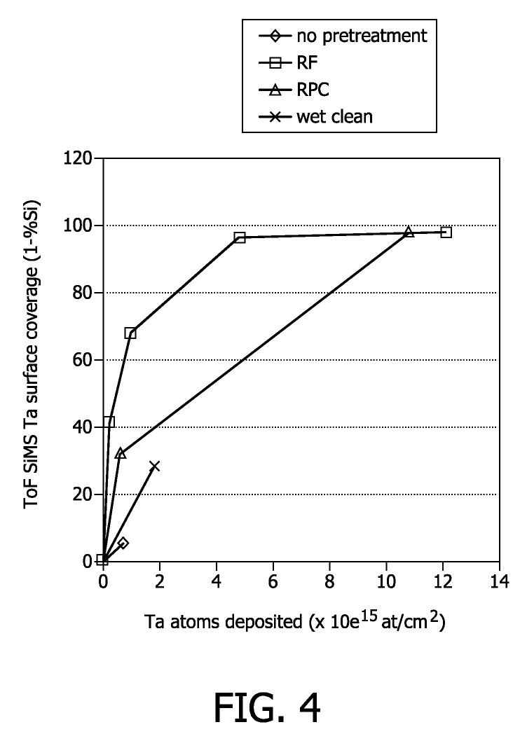

FIG. 4 illustrates a graph showing surface coverage of an ALD film as a function of different surface treatments;

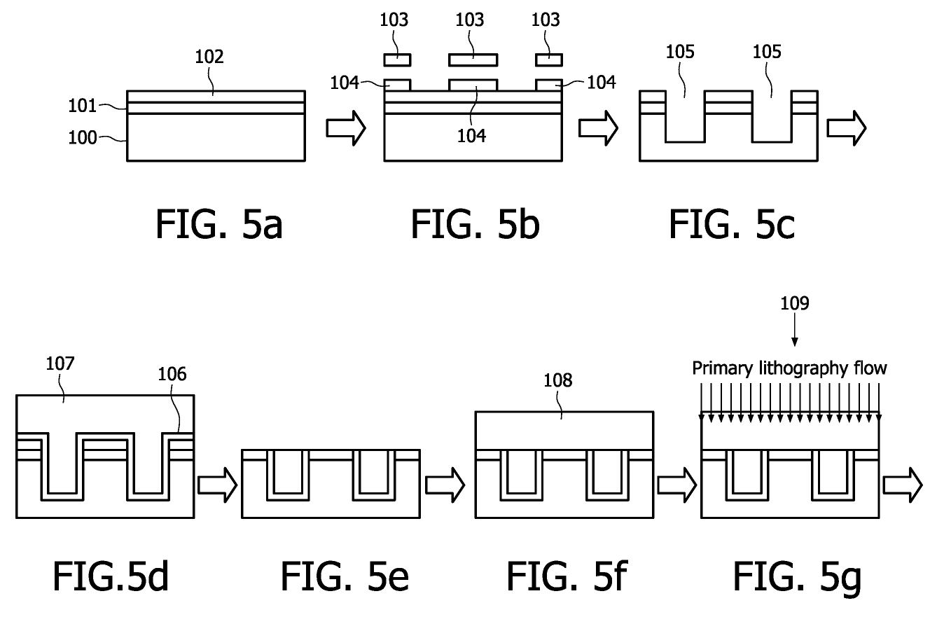

FIGS. 5a to 5k are schematic diagrams illustrating the fabrication of a structure for a semi conductor device.

In a preferred embodiment of the present invention, Atomic Layer Deposition (ALD) is used to selectively deposit a barrier layer on a metal interconnect line in a semiconductor substrate. ALD is a deposition technique that is well known for its uniform, conformal and very controllable deposition behavior. The ALD technique involves sequential pulses of gaseous reactants (or precursors) reacting with a wafer's surface one at a time. Due to adsorbtion of reactants on available surface reaction sites the growth of a layer is self-limiting during a precursor pulse. ALD depends heavily on the density, availability and accessibility of ligands on the wafer surface and their reactivity with the ALD reactants.

Selective Atomic Layer Deposition is made possible by locally passivating the absorption surface, in other words making selected parts of the absorption surface un-reactive to the supplied precursor chemistry.

Many ALD precursors are very reactive towards hydrophilic groups like hydroxyl and amine based ligands that are naturally present on dielectric surfaces. Prior to applying ALD, these hydrophilic groups on a dielectric surface are transformed into hydrophobic groups that are un-reactive to the ALD precursors. Hence, when ALD is applied, local growth on the dielectric surface does not occur, only on the metal surface that is to be capped.

Referring to FIGS. 1a to 1f, a part formed dual damascene structure 1 comprises a dielectric layer 2, a metal via 3 formed in the dielectric layer 2 and a metal diffusion barrier 4 that separates the dielectric layer 2 and the metal via 3. The structure 1 may be formed in accordance with standard practice.

After the metal via 3 has been deposited and chemical-mechanical polishing (CMP) has been performed in accordance with standard practice, corrosion inhibitors 5 are removed by plasma treatment, for example, a hydrogen based plasma treatment.

The plasma treatment exposes hydrophobic groups, for example hydroxyl or amine based ligands, which terminate the dielectric layer 2. In a preferred embodiment, exposed hydroxyl groups are passivated/de-activated by exposing the dielectric layer 2 to hexamethyl disilazane (HMDS) vapour. As is illustrated in FIG. 2, the HMDS vapour 20 replaces hydroxyl groups 21 at the dielectric surface with Si-methyl ligands 23, which are un-reactive towards various ALD precursors at temperatures typically used during ALD.

Atomic Layer Deposition is then preferably carried out in a temperature window of between 200 and 275 degrees Celsius, using pentakis-dimethyl amido tantalum (PDMAT) and NH₃ as precursors. Precursor exposure times are typically longer than 0.5 sec per pulse to allow full saturation of all reactive sites. After around 40 cycles of exposure a Ta₃N₅ barrier 6 of thickness of about 2 nm is obtained on the metal via which is sufficient for capping purposes. Due to the large selectivity towards the metal, the metal line will be substantially covered with the barrier 6. Only very small amounts of barrier 6a are deposited between metal lines on the dielectric (<1e15 at/cm2).

The growth behaviour of the barrier depends upon the density of reactive groups on the surface. As illustrated in FIG. 3, we have observed that the amount of Ta that is deposited on a Cu surface is 50 to 20 times larger than on a methylated e.g. CVD SiOC type material after 20 to 100 cycles of sequential precursor exposure.

The selectivity for precursor adsorption originates from the low amount of reactive surface groups on the SiOC surface (presence of predominantly unreactive methyl groups). Hence, a small amount of precursor molecules will be chemisorbed on a methylated surface compared to copper during the initial stages of growth thus explaining the selectivity of the ALD process. If a large number of cycles are applied on SiOC, the deposition will predominantly take place on material that has been deposited already and an island like type of growth behaviour will occur. If the initial density of active surface groups is small, it will take a large number of cycles before the islands touch each other. In FIG. 4, the surface coverage is shown of the ALD film as a function of different surface pre treatments. The application of an argon or a hydrogen plasma can enhance the number of initial adsorption sites. As long as any plasma surface treatments are avoided the growth rate per cycle will stay small.

Referring back to FIGS. 1e and 1f, a final HF dip is used to remove any barrier 6a that has deposited on the dielectric to avoid the formation of potential leakage paths. Finally, a further di-electic layer 7 is deposited over the first dielectric layer 2 and the barrier 6 in standard fashion.

In an alternative embodiment, which does not make use of HMDS, the dielectric layer 2 is hydrophobic in nature but has a hydrophilic surface, as a result for example of a plasma treatment. In this embodiment, prior to the deposition of the barrier 6 the dielectric layer 2 is treated with an acidic for example a HF wet clean or vapour clean to render the surface of the dielectric layer 2 hydrophobic. The barrier 6 may then be deposited selectively, as described above, over the metal line.

There are several advantages to capping lines in this way with an ALD barrier, in particular the good selectivity of ALD barriers on metallic surfaces compared to hydrophobic surfaces. Additional advantages of ALD include its atomic scale control of growth rate and the conformality of the deposition process. Furthermore, very thin barriers may be used compared to CoWP and there are minimal topography and capacitance increases. There is also minimal outgrowth of the barriers.

A further embodiment of the invention will now be described, the process of which is based on local resin development above reflective metal lines to create a self-aligned open area for barrier deposition. The self-aligned resist development makes use of the reflectivity difference of metal lines and the inter-metal dielectric layer. During a mask less illumination step the threshold of development is reached locally above the metal lines due to the light reflection at the metal-resin interface (“local double exposure”). The illumination dose is adjusted so that the threshold dose of development is obtained over the metal lines and is insufficient in between metal lines where the light is absorbed. The preferred resist is standard 193 nm negative resist so that where the development threshold is reached, the resist can be removed. After resist removal a selective metallic or dielectric barrier is selectively deposited, preferably using ALD deposition methods. The remaining resist is un-reactive towards the ALD precursors so that barrier growth occurs mainly above the metal lines only.

The process is described in more detail with respect to FIGS. 5a to 5k. In a first step of forming an interconnect structure, a layer of anti reflecting dielectric material 101 is deposited over a layer of dielectric 100, for example, a low-K insulator. Anti reflective dielectric materials, for example, bottom anti-reflecting coatings (BARC) are well known materials that substantially absorb rather than reflect photolithographic light flow. A hard mask 102 is then deposited over the layer of anti reflecting dielectric material 101 in standard fashion.

A mask 103 is used in a standard resist spinning step to deposit a pattern of resist negative 104 on the hard mask 102 and photolithographic exposure is carried out.

The resist pattern is transferred through the hard mask 102 in standard fashion to form one or more vias 105 and the resist pattern 104 is removed, for example by plasma etching.

A diffusion barrier layer 106 is formed in a standard way over the side walls of the vias 105 and over the hard mask 102. Next, a metal layer 107, in this example copper, is deposited to fill the vias 105. This is achieved in a standard way by depositing an initial copper seed layer and then filling the vias 105 with copper by electrochemical plating.

Any excess copper above the vias 105, the portion of the barrier layer 106 above the hard mask 102 and the hard mask 102 itself are then removed in a standard fashion by chemical mechanical polishing (CMP).

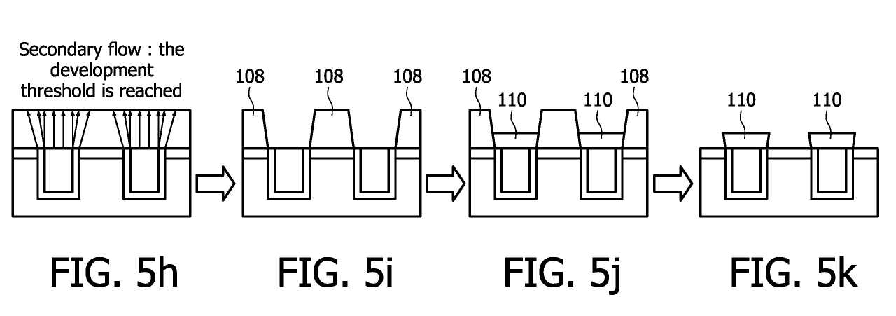

Following this, a layer of conventional 193 nm negative resist 108 is deposited over the layer of anti reflecting dielectric material 101 and the copper 107. Next, the negative resist layer 108 is exposed to a lithographic light flux 109 without the use of a mask. As illustrated in FIG. 6h, the flux is incident substantially perpendicular to the layer 108. Flux that has traveled through the negative resist layer 108 and is incident upon the copper lines 107 is reflected back through the layer 108. However, flux that has traveled through the negative resist layer 108 and is incident upon the anti reflecting dielectric material 101 is absorbed by that material. Consequently, regions of the negative resist layer 108 that are substantially directly above the copper vias 107 are exposed to more flux than are regions of the negative resist layer 108 that are substantially directly above the anti reflecting dielectric material 101. The intensity and duration of the incident light flux 109 is selected such that the development threshold for the negative resist layer 108 is reached in those parts substantially directly above the copper lines 107, but not in those parts substantially directly above the anti reflecting dielectric material 101.

Next, in a standard way, those parts of the resist layer 108 which have developed are removed to reveal the copper lines 107 Then ALD is used to selectively deposit a barrier layer 110 over the copper line 107. The regions of resist layer 108 are not reactive to the ALD pre-cursors, and so little or no growth occurs over these regions. The conditions for applying ALD may be the same as the embodiment described above with reference to FIGS. 1 to 4, that is to say, in a temperature window of between 200 and 275 degrees Celsius, using pentakis-dimethyl amido tantalum (PDMAT) and NH₃ as precursors and with precursor exposure times typically longer than 0.5 sec per pulse.

Following this, the remaining regions of resist layer 108 are removed, for example by a plasma etch or by wet chemical means, leaving barriers 110 localised over the copper line 107, the barriers having only a small lateral overhang.

Finally, a further di-electric layer (not shown) can be deposited over the first dielectric layer 100 and the barriers 110 in standard fashion.

This approach results in well-aligned and well-defined barriers having little lateral outgrowth. The resists and any residues can be easily removed after the selective barrier deposition to avoid the formation of potential leakage paths. In addition, capacitance between metal vias is reduced because there is no use of SiC or SiCN capping and/or an etch stop layer and a USG hard-mask as in known approaches. Moreover, this approach results in a significant improvement in dielectric reliability and electromigration lifetime because of the full metallic encapsulation of the lines.

It will be appreciated that other vapor deposition techniques may be used in embodiments of the invention other than ALD, for example CVD. Although, the embodiments described above relate to the deposition of diffusion barriers in interconnect structures it will be appreciated that embodiments of the invention may be used to deposit other types of layers in various structures for semiconductor devices.

Having thus described the present invention by reference to a preferred embodiment it is to be well understood that the embodiment in question is exemplary only and that modifications and variations such as will occur to those possessed of appropriate knowledge and skills may be made without departure from the spirit and scope of the invention as set forth in the appended claims and equivalents thereof. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements.

A person skilled in the art will readily appreciate that various parameters disclosed in the description may be modified and that various embodiments disclosed and/or claimed may be combined without departing from the scope of the invention.

1. A method of forming a layer over a surface of a first material embedded in a second material in a structure for a semiconductor device, in which method the layer is selectively deposited over the surface of the first material by a vapor deposition step and wherein a surface of the second material is treated prior to the vapor deposition step to inhibit deposition of the layer there on during the vapor deposition step.

2. A method according to claim 1 wherein the vapor deposition step comprises an atomic layer deposition step.

3. A method according to claim 1 wherein the treatment step renders the surface of the second material substantially un-reactive to at least one chemical component used in the vapor deposition step.

4. A method according to claim 3 wherein the treatment step converts the surface of the second material from a hydrophilic surface into a hydrophobic surface.

5. A method according to claim 1, wherein prior to the treatment step the surface of the second material substantially terminates in hydroxyl groups and following the treatment step the surface of the second material substantially terminates in methyl groups.

6. A method according to claim 1 wherein the treatment step comprises exposing the surface of the second material to HMDS vapor.

7. A method according to claim 1 wherein the treatment step comprises cleaning the surface of the second material.

8. A method according to claim 7 wherein the cleaning step comprises an acidic wet clean or an acidic vapor clean.

9. A method according to claim 8 comprising a HF wet clean or a HF vapor clean.

10. A method according to claim 1 wherein the treatment step comprises depositing a third material over the surface of the second material the third material being un-reactive to at least one component used in the vapor deposition step.

11. A method according to claim 1 wherein the treatment step comprises, depositing a layer of resist material across the surface of the first material and across the surface of the second material, irradiating the layer of resist material with lithographic flux such that reflection of the flux by the first material causes a region of the resist material substantially above the first material to develop before one or more regions of the resist material substantially above the second material, removing the region of the resist material substantially above the first material without removing the one or more regions of the resist material substantially above the second material.

12. A method according to claim 11, wherein a layer of anti reflective material is located between the second material and the layer of resist material.

13. A method according to claim 1 wherein the first material is a metal.

14. A method according to claim 13 wherein the metal is copper.

15. A method according to claim 1 wherein the second material is a dielectric.

16. A method according to claim 15 wherein the second material is an ultra low k material.

17. A method according to claim 1 wherein the layer is a diffusion barrier.

18. A method according to claim 2 wherein precursors used during ALD are PDMAT and NH₃.

19. A method according to claim 1 wherein the structure is an interconnect structure.
